(19) United States
(12) Patent Application Publication
(10) Pub. No.: US 2008/0142878 A1
(43) Pub. Date: Jun. 19, 2008

(54) Charge trap memory device and a method of manufacturing the same

(75) Inventors: Sang-moo Choi, Yongin-si (KR); Young-Kwan Cha, Suwon-si (KR); Kwang-soo Seol, Suwon-si (KR); Sang-Jin Park, Yongin-si (KR); Sang-min Shin, Seoul (KR); Ju-hee Park, Guri-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/978,577

(22) Filed: Oct. 30, 2007

(30) Foreign Application Priority Data
Dec. 18, 2006 (KR) 10-2006-0129679

(51) Int. Cl. H01L 29/792; H01L 21/3205

(52) U.S. Cl. 257/325; 438/591; 257/E29.309; 257/E21.423

(57) ABSTRACT

Provided are a charge trap memory device and a method of manufacturing the same. The charge trap memory device may comprise a gate structure including a plurality of metal oxide nanodots discontinuously arranged as a charge trap site on a substrate.

### PRIORITY STATEMENT

This application claims priority under 35 U.S.C. § 119 to Korean Patent Application No. 10-2006-0129679, filed on Dec. 18, 2006, in the Korean Intellectual Property Office (KIPO), the entire contents of which are incorporated herein by reference.

### BACKGROUND

1. Field

Example embodiments relate to a non-volatile memory device and a method of manufacturing the same. Other example embodiments relate to a charge trap memory device using nanodots as a charge trap site and a method of manufacturing the same.

2. Description of the Related Art

A non-volatile memory device is a storage device that does not lose data stored therein when the power is turned off. An example of the non-volatile memory device is a flash memory device. Examples of the flash memory device are a floating gate memory device which may include a floating gate between dielectric layers so as to accumulate charges in the floating gate and a charge trap memory device in which a charge trap layer may be between dielectric layers to be used as a storage node.

An example of a charge trap memory device is a silicon-oxide-nitride-oxide-silicon (SONOS) memory device including a charge trap layer formed of a silicon nitride layer. The SONOS memory device may include a structure in which a source region and a drain region may be formed on a silicon substrate, a tunneling insulating layer, a charge trap layer, and a blocking insulating layer may be stacked on the silicon substrate, and a gate electrode may be formed on the blocking insulating layer. The tunneling insulating layer and the blocking insulating layer may be formed of SiO₂, and the charge trap layer may be formed of a silicon nitride layer (Si₃N₄).

Research has been conducted on a charge trap memory device using nanoparticles as a charge trap site. Metal and semiconductor nanoparticles may have an improved work function, and thus electrons transferred from a silicon substrate electrode may be more stably stored, and thus metal and semiconductor nanoparticles may act as a trap site for storing charges passing through the tunneling insulating layer.

When the charge trap memory device uses storage/emission of charges, programming/erasing speed and charge retention characteristics need to be improved. For example, thickness reduction of the tunneling insulating layer, or the increase of charge traps having a relatively low energy level for rapid programming/erasing speed, may decrease the charge retention characteristics. Also, in order to obtain a relatively large memory window and reduce back-tunneling of electrons, a relatively thick charge trap layer and a blocking insulating layer may be required, which is problematic during scaling-down of the memory device.

With a charge trap memory device based on band gap controlling technology, and high-k dielectric oxide layer and implanting technology of nanodots, the programming/erasing speed and the charge retention characteristics may be increased at the same time by adjusting the energy level of charge traps and increasing the ability of the tunneling insulating layer and the coupling ratio.

With a charge trap memory device using pure metal nanodots as a trap site, a work function may be adjusted to create relatively large charge barriers when charges are retained to increase the charge retention characteristics, and the charge barriers may be lowered during programming/erasing to increase the speed. In other words, the problem of the programming/erasing speed and the charge retention characteristics may be solved.

### SUMMARY

Example embodiments provide a charge trap memory device having improved thermal stability despite using nanodots as a trap site and being capable of increasing programming/erasing characteristics and the charge retention characteristic at the same time and a method of manufacturing the same.

According to example embodiments, a charge trap memory device may include a gate structure on a substrate, wherein the gate structure includes a plurality of metal oxide nanodots discontinuously arranged as a charge trap site.

According to example embodiments, a method of manufacturing a charge trap memory device may include forming a gate structure on a substrate, wherein the gate structure includes a plurality of metal oxide nanodots discontinuously arranged as a charge trap site.

The gate structure may include a tunneling insulating layer, the metal oxide nanodots on the tunneling insulating layer, a blocking insulating layer on the metal oxide nanodots, and a gate electrode on the blocking insulating layer. The charge trap memory device may further include first and second impurity regions on the substrate in contact with the tunneling insulating layer.

The metal oxide nanodots may be conductive. The metal oxide nanodots may have a shape of a nanocrystal, a circle, a half circle and/or an oval. The metal oxide nanodots may be formed of one of RuO₂ and IrO₂. The metal oxide nanodots may be formed using an atomic layer deposition (ALD) method. The gate structure may form one of a planar gate structure and a fin-FET gate structure.

### BRIEF DESCRIPTION OF THE DRAWINGS

Example embodiments will be more clearly understood from the following detailed description taken in conjunction with the accompanying drawings. FIGS. 1-6 represent non-limiting, example embodiments as described herein.

FIG. 1 is a schematic view of a charge trap memory device according to example embodiments;

FIG. 2A is a transmission electronic microscope (TEM) image of a memory device before annealing;

FIG. 2B is a TEM image of the memory device of FIG. 2A after annealing;

FIG. 2C is a TEM image of metal oxide nanodots deposited on a SiO₂ tunneling oxide layer that is formed as a tunneling insulating layer in the memory device of FIG. 2A;

FIG. 3 illustrates the XPS analysis of Ir 4f before and after annealing, according to example embodiments;

FIG. 4 illustrates the analysis of depth profile of elements Ir, Si, and O before and after annealing;

FIGS. 5A and 5B are graphs illustrating electrical characteristics of a charge trap memory device using metal oxide nanodots as a trap site according to example embodiments, the graphs illustrating the programming and erasing characteristics of the charge trap memory device manufactured as a MOSFET; and

FIG. 6 is a schematic view of a memory device according to example embodiments, illustrating a cross-sectional view of main portions of a memory device having a fin-FET gate structure.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. The thicknesses of layers or regions and the size of metal oxide nanodots in the drawings are exaggerated for clarity. Example embodiments may, however, be embodied in many different forms and should not be construed as being limited to the embodiments set forth herein. Rather, these embodiments are provided so that this disclosure will be thorough and complete, and will fully convey the concept of example embodiments to those skilled in the art. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

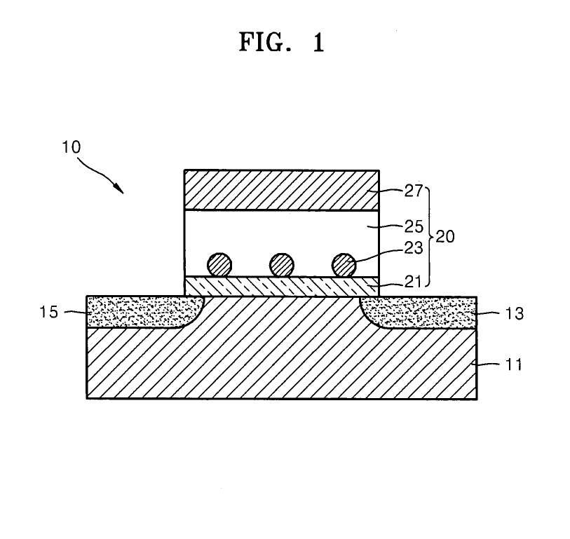

FIG. 1 is a schematic view of a charge trap memory device 10 according to example embodiments. Referring to FIG. 1, the charge trap memory device 10 may include a substrate 11 and a gate structure 20 formed on the substrate 11. Also, first and second impurity regions 13 and 15 doped with a predetermined or given impurity may be formed on the substrate 11. One of the first and second impurity regions 13 and 15 may be a drain region (D), and the other one may be a source region (S).

The gate structure 20 may include a plurality of metal oxide nanodots 23 that are discontinuously arranged as a charge trap site. The metal oxide nanodots 23 may have conductivity so as to retain the characteristics of metal. Also, the metal oxide nanodots 23 may have the shape of a nanocrystal, a circle, a half circle and/or an oval. For example, the metal oxide nanodots 23 may be formed of RuO₂ or IrO₂ nanocrystals having conductivity.

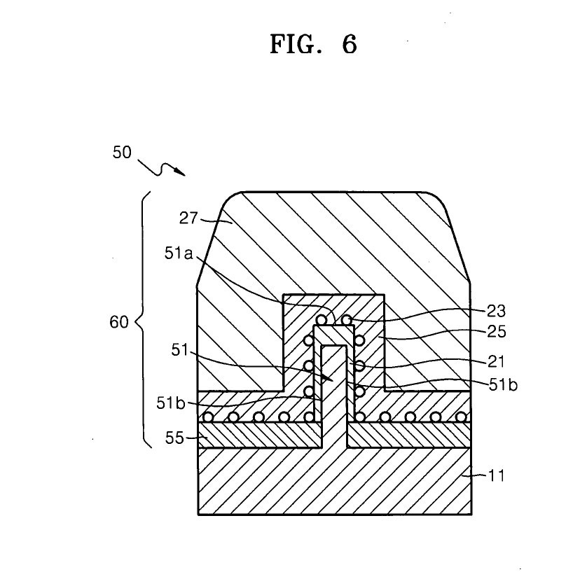

The metal oxide nanodots 23 may be formed using an atomic layer deposition (ALD) method. Thus, when using the ALD method, metal oxide nanodots may be more easily formed in a memory device not only in a two-dimensional structure but also in a three-dimensional structure. Accordingly, the charge trap memory device according to example embodiments may include one of a planar gate structure 20 illustrated in FIG. 1 and a fin-FET gate structure 60 as illustrated in FIG. 6. The gate structure 20 may be a planar gate structure, which is formed by stacking layers on the planar substrate 11.

The gate structure 20 may include a stack formed of a tunneling insulating layer 21, the metal oxide nanodots 23 which are formed on the tunneling insulating layer 21 as a charge storage layer, a blocking insulating layer 25 formed on the metal oxide nanodots 23, and a gate electrode layer 27 formed on the blocking insulating layer 25.

The tunneling insulating layer 21 may be for tunneling charges, and may be formed on the substrate 11 to be in contact with the first and second impurity regions 13 and 15. The tunneling insulating layer 21 may be a tunneling oxide layer, for example, the tunneling insulating layer 21 may be formed of SiO₂, SiN and/or various high-k dielectric oxides. Also, the tunneling insulating layer 21 may also be oxides formed of a combination of the oxides or a multi-layer structure of the oxides. Charges that are tunneled through the tunneling insulating layer 21 may be trapped in the metal oxide nanodots 23.

The blocking insulating layer 25 may block charges from passing through the metal oxide nanodots 23 and moving upward, and may be formed of an oxide layer. The blocking insulating layer 25 may be formed of SiO₂ and/or of a high-k material having a greater permittivity than the tunneling insulating layer 21, e.g., SiON, Si₃N₄, Al₂O₃, HfO₂, Ta₂O₅, ZrO₂, TiO₂, La₂O₃, ScₓO_{y} and/or lanthanide oxide and/or a combination thereof. The blocking insulating layer 25 may be formed as a multi-layer. For example, the blocking insulating layer 25 may be formed of two or more layers by including an insulating layer formed of a general insulating material, e.g., SiO₂ and a high-k dielectric layer formed of a material having a greater permittivity than the tunneling insulating layer 21.

The gate electrode 27 may be formed of a metal layer. For example, the gate electrode 27 may be formed of aluminum (Al) and/or a metal, e.g., Ru and/or TaN and/or a silicide material, e.g., NiSi, which may be used for forming a gate electrode of a semiconductor memory device. In FIG. 1, the metal oxide nanodots 23 may be directly formed on the tunneling insulating layer 21, may function as a charge trap site and may correspond to the charge storage layer. The blocking insulating layer 25 may be formed on the metal oxide nanodots 23 such that the blocking insulating layer 25 may be disposed between the metal oxide nanodots 23 that are discontinuously disposed.

Alternatively, a charge storage layer formed of a non-conductive metal oxide or a dielectric material may be formed on the tunneling insulating layer, and the metal oxide nanodots 23 may act as a charge trap site in the charge storage layer, and the blocking insulating layer 25 may be formed on the charge storage layer.

According to the charge trap memory device 10 of example embodiments, as the metal oxide nanodots 23 having conductivity are formed as a charge trap site, the interface characteristics may not deteriorate but may be maintained during a source/drain activation high temperature annealing process, which may be required when manufacturing a device. Consequently, thermal stability for preserving the electrical characteristics of the memory device 10 may be secured.

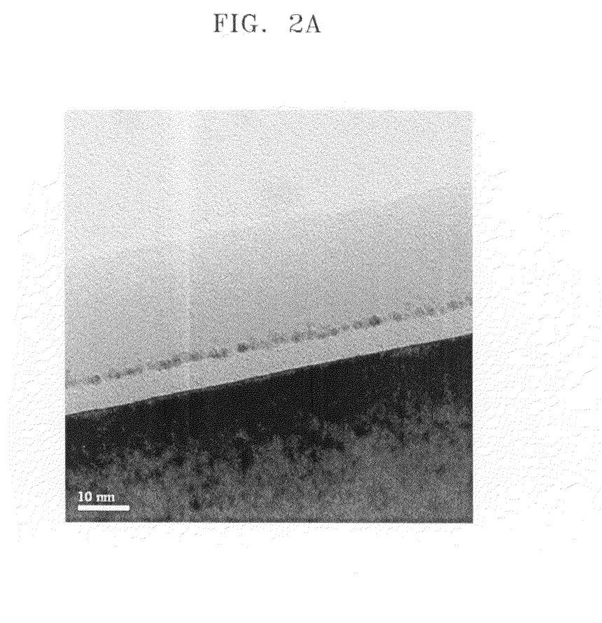

FIGS. 2A-2C are transmission electronic microscope (TEM) images illustrating the structure of a memory device according to example embodiments, the memory device using metal oxide nanodots as a trap site, and the size of the trap site being formed by controlling the conditions of the atomic layer deposition (ALD) method, and differences of the memory device before and after annealing. FIG. 2A is a TEM image of the memory device before annealing, and FIG. 2B is a TEM image of the memory device after annealing, and FIG. 2C is a TEM image of metal oxide nanodots 23 deposited on a SiO₂ tunneling oxide layer formed as a tunneling insulating layer.

The memory device sample illustrated in FIGS. 2A and 2B may include a tunneling insulating layer that is formed of a SiO₂ tunneling oxide layer on a p-type silicon substrate, and IrO₂ nanodots may be formed on the SiO₂ tunneling oxide layer using the ALD method, and then, an Al₂O₃ layer may be formed as a blocking insulating layer. As may be seen from the TEM images of FIGS. 2A-2C, a band of the metal oxide nanodots 23 may be distributed almost parallel to the silicon substrate, and each of the metal oxide nanodots 23 may be distinctively separated.

Also, as may be seen by comparing FIGS. 2A and 2B, there may be no great difference in the shape or distribution of the metal oxide nanodots 23 before and after a high temperature annealing process. By comparing FIGS. 2A and 2B, the metal oxide nanodots 23 may function as a charge storage layer that do not diffuse during a source/drain activation high temperature annealing process which may be required when manufacturing a device, and thus, the interface characteristic may not be deteriorated. Thermal stability for preserving the electrical characteristics of the memory device may be secured.

Also, as illustrated in the TEM image of FIG. 2C, the size and the number of the metal oxide nanodots 23 (stable during a high temperature process) may be about 3.26 nm and about 2.28×10¹² cm⁻², respectively. The metal oxide nanodots 23 in FIG. 2C may be deposited with an RF power of about 500 W and at a substrate temperature of about 400° C. during the ALD process for about 20 cycles in order to be optimized or improved. The size and the number of the metal oxide nanodots 23 may be controlled by controlling the ALD conditions, e.g., the RF power, the substrate temperature, and the number of deposition cycles.

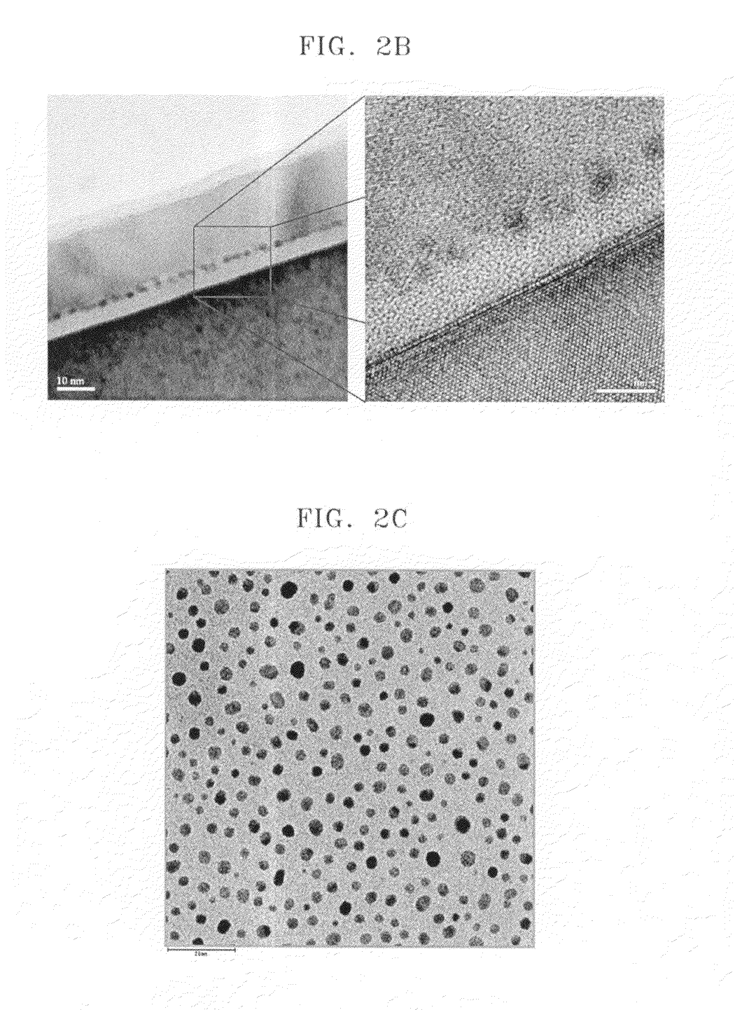

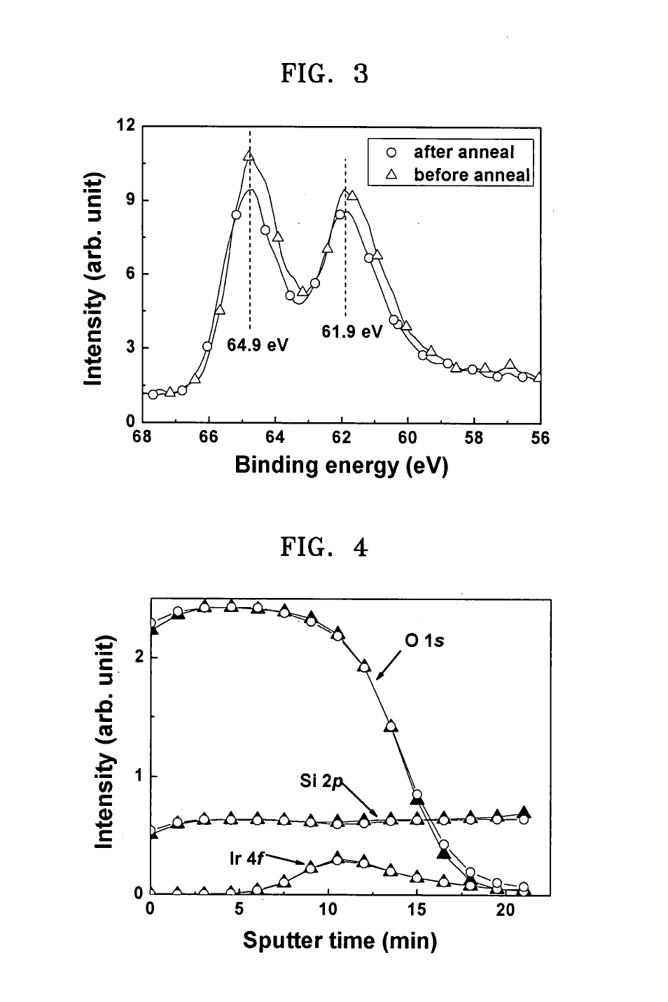

In order to determine the composition of the metal oxide nanodots 23, a sample memory device having a charge storage layer formed of IrO₂ metal oxide nanodots 23 between the SiO₂ tunneling insulating layer and the blocking insulating layer may be manufactured to perform the XPS analysis and the depth profile analysis. The result is illustrated in FIGS. 3 and 4. FIG. 3 illustrates the XPS analysis of iridium (Ir) before and after annealing, and FIG. 4 illustrates the analysis of the depth profile of elements iridium (Ir), silicon (Si), and oxygen (O) before and after annealing. In FIG. 4, the horizontal axis is sputtering time.

In FIG. 3, the locations of the peaks of iridium (Ir) before and after annealing are similar. Also, as may be seen from FIG. 4, the depth profile of the elements iridium (Ir), silicon (Si), and oxygen (O) are also similar. Therefore, the IrO₂ metal oxide, which may be grown using the ALD method, may be thermally stable. The locations of the peaks where the binding energy is about 64.9 eV and about 61.9 eV, respectively, in FIG. 3, correspond to the locations of the peaks where iridium (Ir) is bound to oxygen. The locations of the peaks indicate that the metal oxide nanodots 23 may be formed of IrO₂.

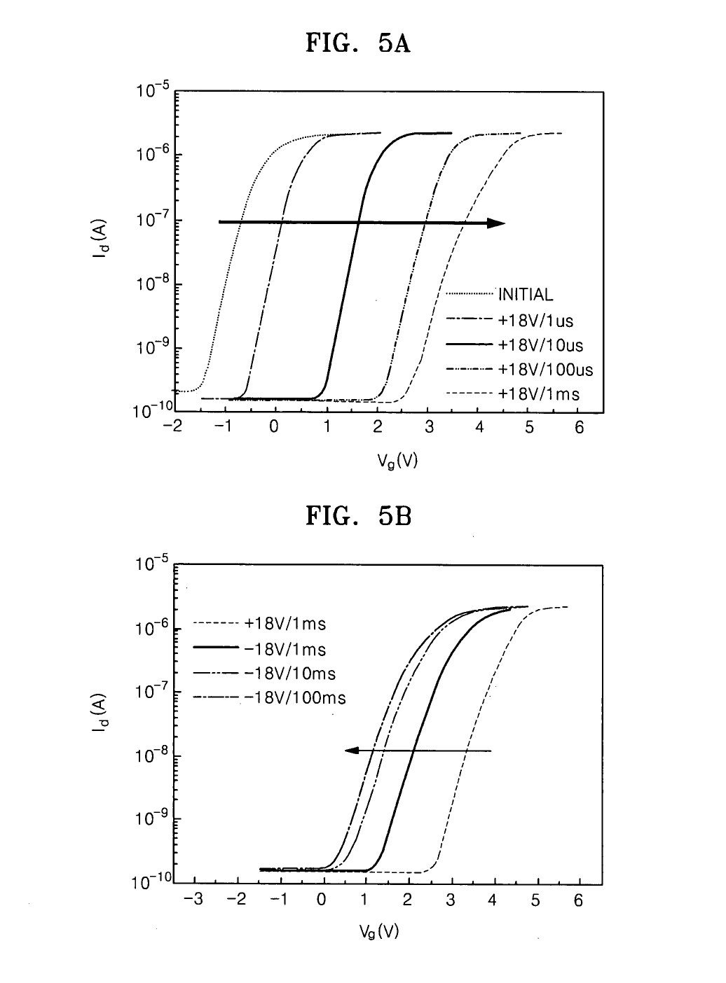

FIGS. 5A and 5B are graphs illustrating electrical characteristics of a charge trap memory device using metal oxide nanodots 23 as a trap site, the graphs illustrating the programming and erasing characteristics of the charge trap memory device according to example embodiments manufactured as a MOSFET. FIGS. 5A and 5B illustrate the electrical characteristics of the charge trap memory device wherein the IrO₂ metal oxide nanodots 23 are included in a charge storage layer. In FIGS. 5A and 5B, the horizontal axis denotes a gate voltage, and the vertical axis denotes a drain current. As illustrated in FIGS. 5A and 5B, the metal oxide nanodots 23 formed of nanocrystals included in the charge storage layer may function as a trap site and may be appropriate for the manufacture of a MOSFET device.

As described above, by including the metal oxide nanodots 23 in a charge storage layer of a non-volatile memory device and using the metal oxide nanodots 23 as a charge trap site, the problem of thermal stability of a conventional memory device including pure metal nanodots may be solved. In addition, a memory device that simultaneously improves programming/erasing speed and charge retention characteristics may be provided.

Also, because the metal oxide nanodots 23 may be formed not only in a two-dimensional structure but also in a three-dimensional structure using the ALD method, a charge trap memory device having a planar gate structure as illustrated in FIG. 1 or a three-dimensional gate structure as in a fin-FET illustrated in FIG. 6 may be realized.

FIG. 6 is a schematic view of a memory device 50 according to example embodiments, the view illustrating a cross-sectional view of main portions of a memory device having a fin-FET gate structure. Common members having the same or similar functions as the members illustrated in FIG. 1 are denoted with the same reference numerals, and description thereof will not be repeated.

Referring to FIG. 6, the memory device 50 may include a substrate 11 and a fin-FET gate structure 60 formed in a three-dimensional structure on the substrate 11. The gate structure 60 may include a tunneling insulating layer 21 that is formed to surround both lateral sides 51b and a top side 51a of a fin 51 that protrudes from the substrate 11, metal oxide nanodots 23 disposed on the region including the tunneling insulating layer 21, a blocking insulating layer 25 formed on the metal oxide nanodots 23, and a gate electrode 27 formed on the blocking insulating layer 25. The gate electrode 27 may be formed across the fin 51. The basic stack of the fin-FET gate structure 60 may be substantially the same as that of the planar gate structure 20 illustrated in FIG. 1, except that some layers forming the gate structure 60 may be formed to cover the fin 51, and the gate electrode 27 may be formed across the fin 51 in order to form a three-dimensional gate structure.

In FIG. 6, the substrate 11 may be formed of a general silicon semiconductor substrate, wherein a device separation region 55 formed of an insulating material may be formed on the substrate 11 except at the region where the fin 51 may be formed. The substrate 11 may also be formed of a silicon-on-insulator (SOI) substrate instead of a general silicon semiconductor substrate, and then, the device separation region 55 illustrated in FIG. 6 may not be required.

The charge trap memory device including the fin-FET gate structure 60 and using the metal oxide nanodots 23 as a charge trap site as illustrated in FIG. 6 may be realized because the metal oxide nanodots 23 may also be formed not only on a planar surface but also on sides of a cubic structure using the ALD method. The metal oxide nanodots 23 may be formed on both sides 51b and the top side 51a of the fin 51 and may function as a charge trap site. The memory device 50 may use the top side 51a and the lateral sides 51b of the fin 51 as a channel region, and thus may have a greater channel area than the memory device 10 including a two-dimensional, planar gate structure 20 as illustrated in FIG. 1.

FIG. 6 illustrates an example of the fin-FET gate structure 60. The structure and form of the fin-FET gate structure 60, except for usage of the metal oxide nanodots 23 having conductivity as a charge storage layer, may be modified in various manners as is well known in the field of memory device technology.

As described above, according to the charge trap memory device of example embodiments, the problem of thermal stability of a conventional memory device including pure metal nanodots may be solved by using the metal oxide nanodots as a trap site, and thus, the programming/erasing characteristics and the charge retention characteristics may be improved at the same time. Also, because a charge storage layer formed of metal oxide nanodots may be formed not only in a two-dimensional structure but also in a three-dimensional structure using the ALD method, a charge trap memory device having a planar structure or a three-dimensional structure, e.g., a fin-FET, may be realized.

While example embodiments have been particularly shown and described with reference to example embodiments thereof, it will be understood by those of ordinary skill in the art that various changes in form and details may be made therein without departing from the spirit and scope of the following claims.

What is claimed is:

1. A charge trap memory device comprising:
a gate structure including a plurality of metal oxide nanodots discontinuously arranged as a charge trap site on a substrate.

2. The charge trap memory device of claim 1, wherein the gate structure includes:
a tunneling insulating layer;
the metal oxide nanodots on the tunneling insulating layer;
a blocking insulating layer on the metal oxide nanodots; and
a gate electrode on the blocking insulating layer.

3. The charge trap memory device of claim 2, further comprising:
first and second impurity regions on the substrate in contact with the tunneling insulating layer.

4. The charge trap memory device of claim 1, wherein the metal oxide nanodots are conductive.

5. The charge trap memory device of claim 4, wherein the metal oxide nanodots have a shape of a nanocrystal, a circle, a half circle, or an oval.

6. The charge trap memory device of claim 4, wherein the metal oxide nanodots are formed of one of RuO₂ and IrO₂.

7. The charge trap memory device of claim 4, wherein the metal oxide nanodots are formed using an atomic layer deposition (ALD) method.

8. The charge trap memory device of claim 7, wherein the gate structure is one of a planar gate structure and a fin-FET gate structure.

9. The charge trap memory device of claim 4, wherein the metal oxide nanodots are formed using an ALD method and the gate structure is one of a planar gate structure and a fin-FET gate structure.

10. The charge trap memory device of claim 9, wherein the metal oxide nanodots are formed of one of RuO₂ and IrO₂.

11. A method of manufacturing a charge trap memory device comprising:
forming a gate structure including a plurality of metal oxide nanodots discontinuously arranged as a charge trap site on a substrate.

12. The method of claim 11, wherein forming the gate structure includes:
forming a tunneling insulating layer on the substrate;
forming the metal oxide nanodots on the tunneling insulating layer;
forming a blocking insulating layer on the metal oxide nanodots; and
forming a gate electrode on the blocking insulating layer.

13. The method of claim 12, further comprising:
forming first and second impurity regions on the substrate in contact with the tunneling insulating layer.

14. The method of claim 11, wherein the metal oxide nanodots are conductive.

15. The method of claim 14, wherein the metal oxide nanodots have a shape of a nanocrystal, a circle, a half circle, or an oval.

16. The method of claim 14, wherein the metal oxide nanodots are formed of one of RuO₂ and IrO₂.

17. The method of claim 14, wherein the metal oxide nanodots are formed using an atomic layer deposition (ALD) method.

18. The method of claim 17, wherein the gate structure is one of a planar gate structure and a fin-FET gate structure.

19. The method of claim 14, wherein the metal oxide nanodots are formed using an ALD method and the gate structure is one of a planar gate structure and a fin-FET gate structure.

20. The method of claim 19, wherein the metal oxide nanodots are formed of one of RuO₂ and IrO₂.
